(19) United States
(12) Patent Application Publication
(10) Pub. No.: US 2008/0023715 A1
(43) Pub. Date: Jan. 31, 2008

(54) Method of Making White Light LEDs and Continuously Color Tunable LEDs

(76) Inventor: Hoi Wai CHOI, Kennedy Town (HK)

Correspondence Address: COOPER & DUNHAM, LLP, 1185 AVENUE OF THE AMERICAS, NEW YORK, NY, 10036, US

(21) Appl. No.: 11/780,082

(22) Filed: Jul. 19, 2007

Related U.S. Application Data
(60) Provisional application No. 60/820,679, filed on Jul. 28, 2006.

(51) Int. Cl. H01L 33/00

(52) U.S. Cl. 257/98; 438/27; 257/E33.061

(57) ABSTRACT

A light emitting diode comprising of a fluorescent microsphere coating is proposed. The coating consists of fluorescent microspheres which fluoresce at green and red wavelengths, excited by a shorter wavelength LED. Due to the micron-scale dimension of the spheres, they are non-resolvable to the human eye and the overall optical output appears as color mixed. By varying the proportions of green and red fluorescent microspheres and the wavelength of the excitation source, the color of the optical output can be tuned. If the optical output has of blue, green and red components in the correct proportions, white color emission can be achieved. The light emitting diode can be sectioned into multiple individually-addressable regions. Each section can emit at a different wavelength according to the type of fluorescent microspheres coated. By varying the intensity of the blue, green and red regions by changing the bias voltage, the output wavelength (color) can be continuously tuned (varied).

### CROSS REFERENCE TO RELATED APPLICATION

This application claims priority based on U.S. Provisional Patent Application No. 60/820,679, filed Jun. 28, 2006, the entire contents of which are incorporated herein by reference.

### FIELD OF THE INVENTION

The present invention relates to Light Emitting Diode (LED) devices. In particular, it involves usage of fluorescent microspheres for wavelength (color) conversion, and the implementation of a color tunable LED.

### BACKGROUND OF THE INVENTION

Light emitting diodes are optoelectronic devices, which emit light by recombining the injected electrons and holes radiatively. Depending on the bandgap of the active material in the device, LEDs can emit at a wide range of wavelengths from ultraviolet to infrared. However, the wavelengths of light which are of major interest are in the visible region. LEDs emitting in the visible spectrum (typically from ˜400 nm (purple) to ˜700 nm (red)) are visible to the human eye and are thus useful for illumination purposes. In order to emit light at visible wavelengths, the group III and V elements which are typically used are gallium (Ga), indium (In) and nitrogen (N). These materials are doped with impurities from other columns of the periodic table to allow electrical activity, which in turn generates light via the recombination of an electron from a conducting state to a valence state.

The devices above are of the (In,Ga) N material group. LEDs fabricated from this material system have been demonstrated. LEDs are monochromatic light sources which emits with single spectral peak and a narrow linewidth (˜30 nm). LEDs fabricated using the (In,Ga) N material system can be made to emit monochromatic light ranging from ˜380 nm (near-UV) to ˜540 nm (green) by changing the indium composition in the material system. LEDs, with their monochromatic nature, are useful in applications such as light indicators.

White light, on the other hand, is broadband, polychromatic light that cannot be generated directly with an LED. However, if an LED can be made to generate light at a number of discrete or continuous wavelengths, the resultant spectrum will be polychromatic and the emission from such an LED will appear as white. This is particularly useful because white light is ideal for illumination purposes. LEDs as illumination light sources are superior to other technologies such as incandescent lamps and fluorescent tubes in efficiency, lifetime, and spectral pureness.

There are two major methods of making broadband LED light sources. The first makes use of phosphors for color down-conversion. In these systems, a shorter wavelength monochromatic LED, such as an InGaN LED emitting at 460 nm (blue), is used as an excitation light source. Such light is used to excite luminescence in phosphors emitting at longer wavelengths, such as green and red. The resultant light includes components from different parts of the visible spectrum, and is considered broadband light. Since the phosphor particles are small (nanometer scale) and indistinguishable to the eye, the emitted light appears as white, if the proportions of the different colors are right. This form of white light generation is similar to that employed in fluorescent tubes.

White light LED technology using phosphors for color down-conversion has been developed, but its output includes the presence of spikes in the output spectrum. Such spectral characteristics may be irritating and uncomfortable to the human eye.

Another method of making a broadband LED light source is to mount discrete LED chips in a single package. These are typically called multi-chip LEDs, where LEDs emitting at the primary colors (blue, green and red) are mounted in a single package. However, white light emission cannot be achieved using this technique. Each LED chip is typically over 100 microns in diameter, while the separation of LED chips is of the same order. As a result, the colors are not homogenized, and appear as discrete colors to the eye, unless placed far apart, in which case the LED intensity has dropped immensely.

While the discrete RGB LEDs in the device mentioned in the paragraph above can be driven individually, and permit varying the intensities of the various color components, the colors are not mixed and thus do not constitute a color tunable device. True color tunable LEDs have not as yet appeared in the market.

### SUMMARY OF THE INVENTION

The invention provides a method for making a white light emitting light emitting diode (LED). The method comprises providing an LED base pump having a light emitting surface that emits light having a wavelength of about 400 nm to about 480 nm; depositing red and green spreading the fluorescent microspheres on the light emitting surface of the LED base pump to produce a fluorescent microsphere layer; and affixing the fluorescent microsphere layer with a dielectric layer or coating.

The invention further provides a white light emitting diode (LED), comprising an LED base pump that emits light in the shorter wavelength region (about 400 nm to about 480 nm) as a pump source for the white light emitting LED; at least one layer of red and green fluorescent microspheres adhered to the LED base that emit red and green colored light in microscale regions when excited by the light emitted by the LED base pump such that the microscale regions are not resolvable by the unaided human eye and thus appear to emit white light.

The invention also provides a method for making a mixed color, tunable light emitting diode (LED), comprising providing an LED base pump light source having a light emitting surface that emits light having a wavelength of about 400 nm to about 480 nm; forming a plurality of green pixels on a region of the LED base pump by coating the region with green fluorescent microspheres; forming a plurality of red pixels on a region of the LED base pump by coating the region with red fluorescent microspheres; connecting the plurality of green pixels to one another and the plurality of red pixels to one another using a thin layer of gold metal; permitting a region of the light emitting surface to remain uncoated to create blue pixels; depositing a thin layer of silicon dioxide on inactive regions to prevent shorting of p-n junctions on the base LED pump; and depositing a thin layer of silicon dioxide on the pixels to form a protective cover on the mixed color, tunable light emitting diode.

The invention additionally provides a color mixed, color tunable light emitting diode (LED), comprising an LED base pump light source having a light emitting surface that emits light having a wavelength of about 400 nm to about 480 nm; a plurality of green pixels provided on a region of the LED base pump by coating green fluorescent microspheres onto the region; a plurality of red pixels provided on a region of the LED base pump by coating red fluorescent microspheres onto the region; a plurality of blue pixels on an uncoated region of the LED base pump; the green pixels connected to one another and the red pixels connected to one another using a thin layer of gold metal; a thin layer of silicon dioxide on inactive regions of the gold metal layer to prevent shorting of p-n junctions on the base LED pump; and a thin layer of silicon dioxide on the pixels to form a protective cover on the color tunable light emitting diode.

### BRIEF DESCRIPTION OF THE DRAWINGS

Further features and advantages of the invention will become apparent upon review of the following detailed description of the preferred embodiments taken in conjunction accompanying figures, in which:

FIG. 1 shows color emission using in LEDs including fluorescent microspheres according to the present invention;

FIG. 2 shows ordered packing of microspheres into a hexagonal array in (a) plan and (b) oblique angle views;

FIG. 3 shows the color mixing effect in the present invention;

FIG. 4 shows a white light LED using the fabrication method proposed in this invention;

FIG. 5 shows optical spectrum from white light LED fabricated using the fabrication method according to the present invention;

FIG. 6 shows a schematic diagram of the layout of the color-tunable LED, illustrating the interconnection scheme of R, G, and B pixels using metal lines;

FIG. 7 shows a microphotograph of the fabricated color-tunable LED of the present invention; and

FIG. 8(a) shows the color tunable LED in accordance with the present invention with the “blue” pixels turned on, representing one-third of the pixel array. FIG. 8(b) shows the “red” pixels are turned on.

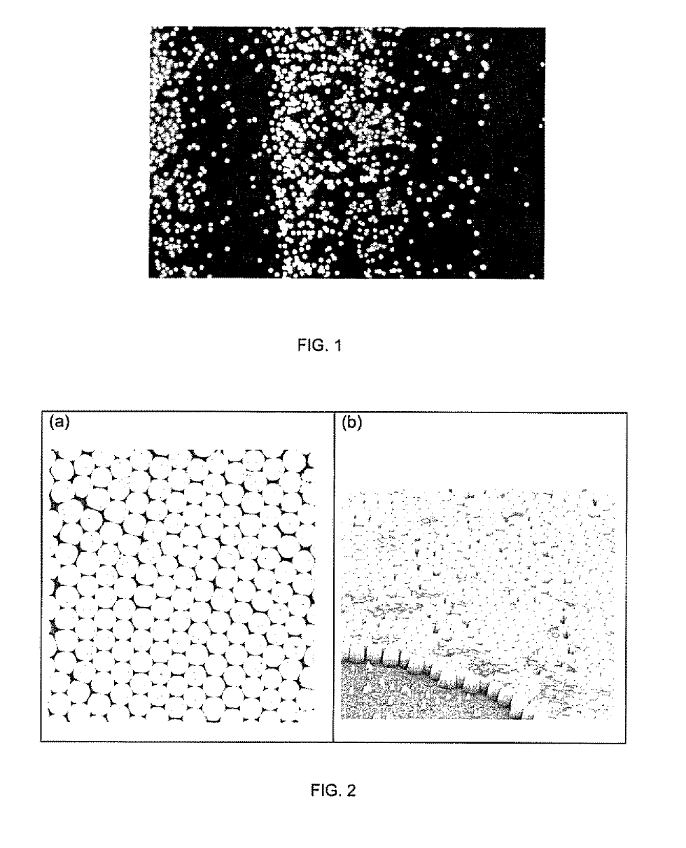

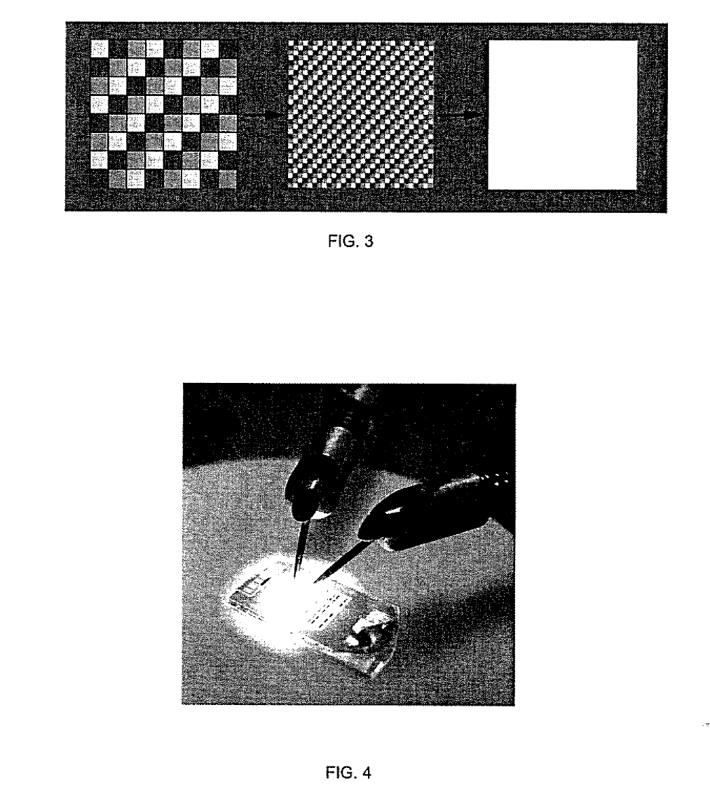

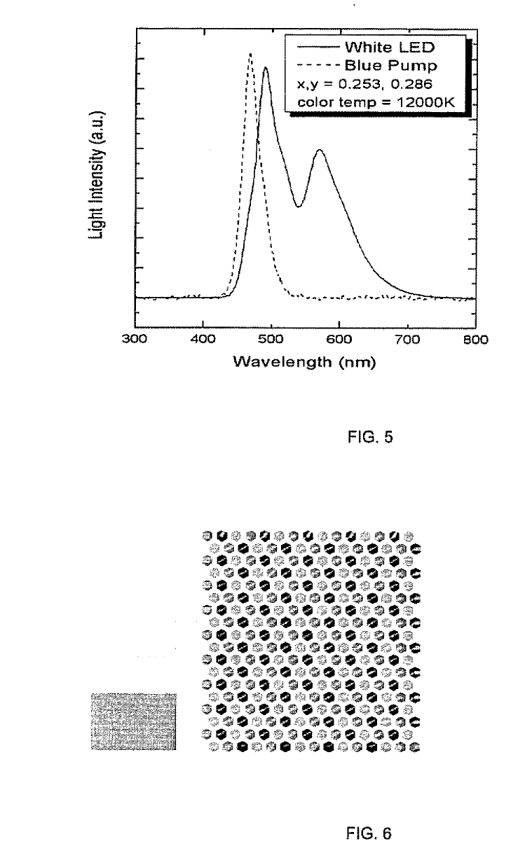

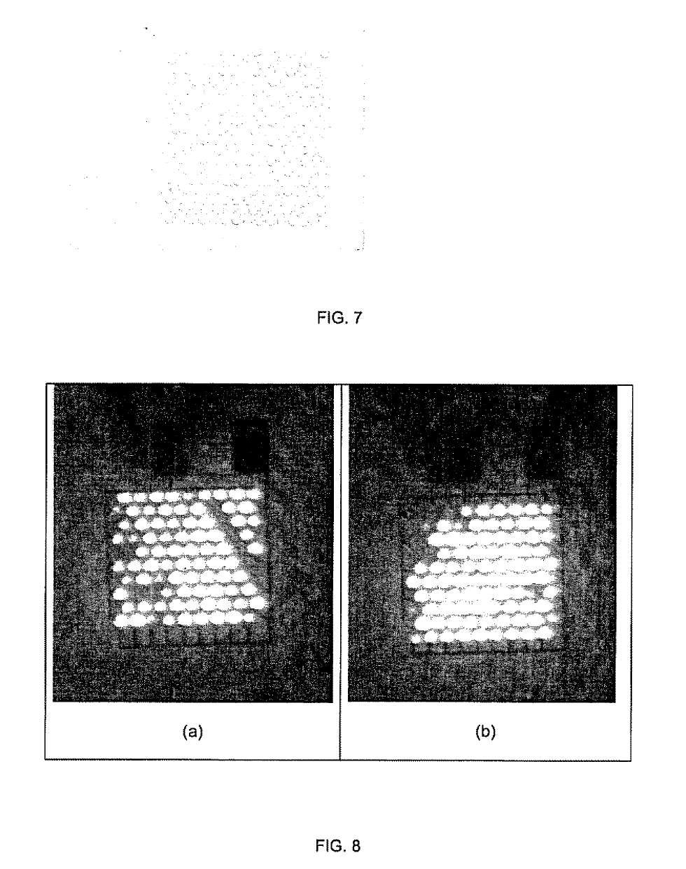

### DETAILED DESCRIPTION OF THE PREFFERRED EMBODIMENTS

The present invention flows from the discovery that the use of a color conversion scheme, together with micro-LED technology, enables a number of novel devices to be fabricated, including white light LEDs and wavelength-tunable LEDs, which would not be feasible or possible using previous technologies such as phosphors.

The present invention includes two major parts: The first part of the invention proposes the use of green and red color dyed fluorescent microspheres as agents for color conversion in white light LEDs; while the second part of the invention proposes the use of microspheres combined with micro-light-emitting diodes (micro-LED) technology for making color tunable LEDs.

Turning to the first aspect, a mixture of red and green dyed fluorescent microspheres are coated onto a short wavelength emitting LED, typically with emission wavelength between 400 nm (purple) to 480 nm (blue). Such an LED is fabricated using an LED wafer, with GaN material grown epitaxially by MOCVD on a sapphire substrate. A series of multi-quantum wells are embedded in the LED structure to achieve the desired emission wavelength.

The LED is fabricated by first defining the mesa region of an LED using photolithography. A layer of photoresist is spin-coated onto an LED wafer, and is exposed to ultraviolet light through a photo mask with the pre-defined pattern on a mask-aligner. The exposed sample is developed in a photoresist developer. The required pattern is transferred onto the sample.

The mesa structure is subsequently formed using inductively-coupled plasma (ICP) dry etching with Cl₂ and BCl₃ gases, The GaN material is etched away at a typical rate of 500 nm/min. Another photolithography step defines the active region of the LED. The wafer is dry etched again using the same ICP recipe, exposing a portion of the n-type GaN region for subsequent n-contact.

The current spreading region is defined by photolithography; a current spreading layer comprising 5 nm of Au and 5 nm of Ni is deposited by electron beam evaporation. The metal layer is then lifted off in acetone, so that the metal bi-layer remains in the current spreading region. This layer acts as the p-type contact to the device. The n-type and p-type contact pad regions are defined by photolithography.

A Ti/Al metal bi-layer with thicknesses of 201200 nm respectively is deposited by electron beam evaporation. The metal layer is lifted off in acetone, so that metal only remains in the contact pad regions, acting as the n- and p-type contact pads.

The wafer is sliced using a wafer sawing machine; individual LED chips are obtained. The chips are mounted onto either TO-cans or ceramic packages with silver-coated mirror cavity (Kyocera Corporation) using a highly thermal conductive adhesive (Loctite 315 adhesive and Loctite Output activator). Connection between the p- and n-type pads and the package is established by wire-bonding; 50 μm Al wire was employed for this purpose using a wedge-type wire-bonder.

Fluorescent microspheres are typically suspended in deionied (DI) water. Their dimensions range from tens of nanometers to tens of microns in diameter. The microspheres used are supplied by Duke Scientific Corporation and Merck Estapor. The microspheres are to be coated uniformly onto the surface of the excitation LED light source. The suspension of microspheres is dispensed onto the sample using a dropper, syringe or pipette. To spread the microspheres uniformly over a wide region, the sample is placed onto a spinner for spinning at low speeds. Typical rotation speeds of 1-5 rpm are used for this process.

The microspheres may also be spread out by tilting. After applying the microsphere suspension onto the LED chip, the sample is tilted to an angle of about 45 degrees to the vertical. The microsphere coating should be thin; that is, the thickness should be no more than a few monolayers. If this is achieved, the microspheres organize themselves into a hexagonal array. This becomes a self-assembled ordered array of nano-particles.

With an ordered array of fluorescent microspheres, the light conversion efficiency is at optimum as a result of volumetric light scattering. The fluorescent microspheres can be fixed in place and protected by coating an dielectric layer, usually SiO₂₁ using electron beam evaporation. An epoxy-type encapsulant is applied over the microsphere-coated chip to protect the LED from the external environment.

Another method of microsphere coating is to pre-mix the microspheres with the encapsulant. The microsphere suspension is placed into a test-tube and heated to remove the water content. Encapsulant is added into the test-tube. The test-tube is placed onto a shaker for uniform mixing. The mixture can then be applied to the packaged LED using a dropper, syringe or pipette.

With a purple or blue LED acting as a pump source, the microspheres emit green and red color light respectively. Since the microspheres are non-resolvable to the human eye, the colors appear as mixed instead of being individually distinguishable. The colors emitted include blue (from the LED pump source), green and red (from the microspheres). With the inherent mixing effect, the overall light emission appears white in color. This effect is exploited for the use as white light LEDs.

The second part of the invention proposes the use of microspheres, combined with micro-light-emitting diodes (micro-LED) technology, for making color tunable LEDs. As before, a blue or purple LED is used as a pump source for exciting fluorescent microspheres. This LED is sectored in micron-scale regions, with each region not exceeding an area of about 50×50 microns, such that each region is not resolvable to the human eye. Each of these regions is called a pixel. The initial process flow for this device is similar to that for the white LED as described above.

Formation of the micro-scale pixels in the active region occurs with another set of photolithography and etching steps. The micro-scale pattern is transferred from a photomask onto the photoresist-coated LED wafer and developed. This pattern is subsequently transferred to the LED material by plasma dry etching using Cl₂ and BCl₃ as process gases.

One-third of the pixels are designated as blue, green and red pixels respectively. All pixels of the same color are interconnected. This is achieved with a gold metal interconnection layer of about 200 nm in thickness. To prevent this metal layer from shorting the p-n junctions, a thin 20 nm silicon dioxide insulating layer has been deposited onto the non-active regions using a combination of electron-beam evaporation and lift-off.

Green and red fluorescent microspheres are coated onto their respective pixels to form green light and red light emitting pixels. Blue pixels are uncoated, since the source itself is emitting at this color.

To coat the green pixels, another masking step is required. A photoresist mask is applied and developed, so that the location of the green pixels are exposed without photoresist. The green fluorescent microspheres are then applied to the entire sample by spin-coating. A thin layer of silicon dioxide of 20 nm is deposited on top of the device by electron beam lithography. This encapsulation layer fixes the green fluorescent microspheres in place on top of the green pixels. The method for coating the red pixels with red fluorescent microspheres is similar to that of the green pixels.

Since pixels emitting at the same color are interconnected by metal interconnects, they can be addressed (turned on and off, or have the intensity) changed simultaneously.

By changing the intensity of the blue, green and red pixels by varying the voltage bias, the color of the mixed optical output can be continuously varied, producing a revolutionary truly single-chip color-mixed color tunable LED.

For the purpose of fabricating a color-tunable LED, the color conversion agent employed is not confined to the use of fluorescent microspheres. Other materials, including but not limited to phosphors, polymers and quantum dots may be used.

The fabrication process of the white LEDs or the color tunable LEDs of the present invention is the same as the fabrication of GaN-based LEDs, which involves standard lithography, dry etching, metal deposition, die separation and packaging processes, which can all be readily manufactured at a commercial III-V fabrication facility. The additional step of microsphere coating can be done by spin-coating, using a piece of equipment called a spinner. This is a piece of standard equipment in a cleanroom. Micro-sectioning of a color-tunable LED requires an additional masking and etch step, which are standard processes in LED manufacturing.

We have identified a number of advantages of using fluorescent microspheres for color down-conversion with applications in white light LEDs and color tunable LEDs. First, the micron to sub-micron scale dimensions of microspheres ensures that they are not resolvable to the human eye (our eye is able resolve features of down to about 50 microns). When multiple microspheres fluoresce, the human eye is unable to distinguish between emission from individual microspheres. As such, uniform color mixing is easily and readily achieved by mixing a variety of differently-dyed fluorescent microspheres.

Next, differently-dyed microspheres with differing emission wavelengths can be mixed in varying proportions to achieve white light with different degrees of “whiteness.” that is, different color temperatures. In addition, fluorescent microspheres have high conversion efficiencies. This is important for making optoelectronic devices with high luminous efficiencies.

It should be apparent to a person of skill in the art that a white light LED and a color tunable LED have been disclosed and described, along with a method of manufacture thereof that provides ease of manufacture, using inexpensive readily available materials, including a blue and purple light emitting diode chop as a base.

Various alterations and modifications to the preferred embodiments described above will be apparent to those of skill in the art upon review of the foregoing detailed description. Such changes and modifications can be made without departing from the spirit or scope of the present invention, and it is therefore, intended that all such changes and modifications be covered within the definition of the invention as set forth by the following claims.

What is claimed is:

1. A method for making a white light emitting light emitting diode (LED), comprising:
providing an LED base pump having a light emitting surface that emits light having a wavelength of about 400 nm to about 480 nm;
depositing red and green fluorescent microspheres on the light emitting surface of the LED base pump with;
spreading the red and green microspheres on the light emitting surface of the LED base pump to produce a microsphere layer; and
affixing the microsphere layer with a protective dielectric layer or coating.

2. A method according to claim 1, wherein the dielectric layer or coating is silicon dioxide applied by electron beam evaporation.

3. A method according to claim 1, wherein the red and green microsphere layer on the LED base includes several monolayers of red and green microspheres organized into a hexagonal array.

4. A method according to claim 1, additionally comprising encapsulating the white light emitting LED with an encapsulant to protect the white light emitting LED.

5. A method according to claim 1, wherein the fluorescent microspheres are spread in an even layer using tilting or spinning.

6. A method according to claim 1 wherein the red and green fluorescent microspheres are suspended in deionized water before application to the light emitting surface of the base LED base pumpby tilting or spinning.

7. A method according to claim 1, wherein the red and green fluorescent microspheres are mixed with an encapsulating agent and then applied to the light emitting surface of the LED base pump.

8. A method according to claim 1, wherein the encapsulating agent is an epoxy based resin.

9. A method according to claim 1, wherein the red and green fluorescent microspheres are located in distinct regions to form red and green pixels, and the red and green pixels are interconnected with a gold metal interconnection layer.

10. A method for making a mixed color, tunable light emitting diode (LED), comprising:
providing an LED base pump light source having a light emitting surface that emits light having a wavelength of about 400 nm to about 480 nm;
forming a plurality of green pixels on a region of the LED base pump by coating the region with green fluorescent microspheres;
forming a plurality of red pixels on a region of the LED base pump by coating the region with red fluorescent microspheres;
connecting the plurality of green pixels to one another and the plurality of red pixels to one another using a thin layer of gold metal;
permitting a region of the light emitting surface to remain uncoated to create blue pixels,
depositing a thin layer of silicon dioxide on inactive regions to prevent shorting of p-n junctions on the base LED pump; and
depositing a thin layer of silicon dioxide on the pixels to form a protective cover on the mixed color, tunable light emitting diode.

11. A white light emitting diode (LED), comprising:
an LED base that emits light in the shorter wavelength region (about 400 nm to about 480 nm) as a pump source for the white light emitting LED;
at least one layer of red and green fluorescent microspheres adhered to the LED base that emit red and green colored light in microscale regions when excited by the light emitted by the LED base such that the microscale regions are not resolvable by the unaided human eye and thus appear to emit white light.

12. A white light emitting diode (LED) according to claim 11, wherein the ratio of red and green microspheres can be altered to produce a different color.

13. A white light emitting diode (LED) according to claim 11, wherein the at least one layer of fluorescent red and green microspheres include multiple individually addressable microscale regions or pixels which emit one of blue, red or green colored light.

14. A white light emitting diode (LED) according to claim 11, wherein the LED base emits blue colored light and the fluorescent microspheres emit red or green light.

15. A white light emitting diode (LED) according to claim 13, wherein the blue, green, and red light each have intensity that is individually adjustable.

16. A white light emitting diode (LED) according to claim 11, wherein output wavelength of the base LED and the red and green microspheres is continuously tunable.

17. A color mixed, color tunable light emitting diode (LED), comprising:
an LED base pump source having a light emitting surface that emits light having a wavelength of about 400 nm to about 480 nm;
a plurality of green pixels provided on a region of the LED base pump by coating green fluorescent microspheres onto the region;
a plurality of red pixels provided on a region of the LED base pump by coating red fluorescent microspheres onto the region;
a plurality of blue pixels on an uncoated region of the LED base pump;
the green pixels connected to one another and the red pixels connected to one another using a thin layer of gold metal;
a thin layer of silicon dioxide on inactive regions of the gold metal layer to prevent shorting of p-n junctions on the base LED pump; and
a thin layer of silicon dioxide on the pixels to form a protective cover on the color tunable light emitting diode.
